(19) United States
(12) Patent Application Publication
(10) Pub. No.: US 2017/0016110 A1
(43) Pub. Date: Jan. 19, 2017

(54) DOUBLE-VALVE DEVICE FOR A FILM DEPOSITION APPARATUS

(71) Applicant: Linco Technology Co., LTD., Taichung City (TW)

(72) Inventors: Yi-Yuan Huang, Taichung City (TW); Mu-Sen Lu, Taichung City (TW); Wen-Lung Chen, Taichung City (TW)

(73) Assignee: Linco Technology Co., LTD, Taichung City (TW)

(21) Appl. No.: 14/798,555

(22) Filed: Jul. 14, 2015

(51) Int. Cl. C23C 14/56; C23C 14/50

(52) U.S. Cl. CPC C23C 14/56; C23C 14/50

(57) ABSTRACT

A double-valve device includes a base unit, two valve units and a transport unit. The base unit has a surrounding wall, an entrance wall connected to the surrounding wall and formed with an entrance opening, an exit wall connected to the surrounding wall oppositely of the entrance wall and formed with an exit opening, and a spacing wall disposed between the entrance and exit walls and formed with a pass-through opening. The surrounding wall, the entrance wall and the spacing wall cooperatively define a buffer chamber. The surrounding wall, the spacing wall and the exit wall cooperatively define a joint chamber. The valve units are respectively disposed in the buffer and joint chambers for respectively sealing and unsealing the entrance and pass-through openings.

### FIELD

The disclosure relates to a valve device, more particularly to a double-valve device for a film deposition apparatus.

### BACKGROUND

Physical vapor deposition (PVD) is a technique used for physically depositing a thin film on a workpiece. An ultrahigh vacuum environment is required for performing a PVD process, PVD is therefore also called vacuum film deposition. A conventional vacuum film deposition apparatus has a process chamber in which the workpiece is deposited with the thin film, an unload chamber interconnecting the process chamber and the environment, and a valve disposed between the process chamber and the unload chamber. After the workpiece is removed from the process chamber, the valve hermetically seals the process chamber for the process chamber to be pumped down to ultrahigh vacuum by a vacuum pump, so that the process chamber is ready for another workpiece to be processed therein.

However, after long-term use of the conventional vacuum film deposition apparatus, hermetical sealing effect and the vacuum level of the process chamber may deteriorate due to film deposition on the valve. The thin film quality on the workpiece is therefore adversely affected.

### SUMMARY

Therefore, an object of the disclosure is to provide a double-valve device for a film deposition apparatus that can achieve effective hermetical sealing effect even after long-term use.

According to an aspect of the present disclosure, a double-valve device is adapted to be mounted between a process chamber and an unload chamber of a film deposition apparatus. The double-valve device includes a base unit, two valve units and a transport unit.

The base unit has a surrounding wall, an entrance wall connected to one side of the surrounding wall and formed with an entrance opening, an exit wall connected to another side of the surrounding wall oppositely of the entrance wall and formed with an exit opening, and a spacing wall disposed between the entrance and exit walls and formed with a pass-through opening. A maximum distance between the entrance and exit walls is not greater than 500 millimeters. The surrounding wall, the entrance wall and the spacing wall cooperatively define a buffer chamber. The surrounding wall, the spacing wall and the exit wall cooperatively define a joint chamber. The entrance wall is adapted to be hermetically connected to the process chamber. The exit wall is adapted to be hermetically connected to the unload chamber. The base unit further has a pumping hole that is in spatial communication with the buffer chamber.

The valve units are respectively disposed in the buffer and joint chambers for respectively sealing and unsealing the entrance and pass-through openings.

The transport unit includes a roller rotatably disposed in the buffer chamber.

### BRIEF DESCRIPTION OF THE DRAWINGS

Other features and advantages of the present disclosure will become apparent in the following detailed description of the embodiment with reference to the accompanying drawings, of which:

FIG. 1 is a fragmentary side view of an exemplary embodiment of a double-valve device according to the present disclosure interconnecting a process chamber and an unload chamber;

FIG. 2 is a fragmentary cross-sectional view of the exemplary embodiment interconnecting the process chamber and the unload chamber, showing two valve units at an unsealing position;

FIG. 3 is a view similar to FIG. 2, but showing the two valve units at a sealing position;

FIG. 4 is a cross-sectional view of the exemplary embodiment taken along line IV-IV of FIG. 1;

FIG. 5 is a cross-sectional view of the exemplary embodiment taken along line V-V of FIG. 4; and

FIG. 6 is a cross-sectional view of the exemplary embodiment taken along line VI-VI of FIG. 4.

### DETAILED DESCRIPTION

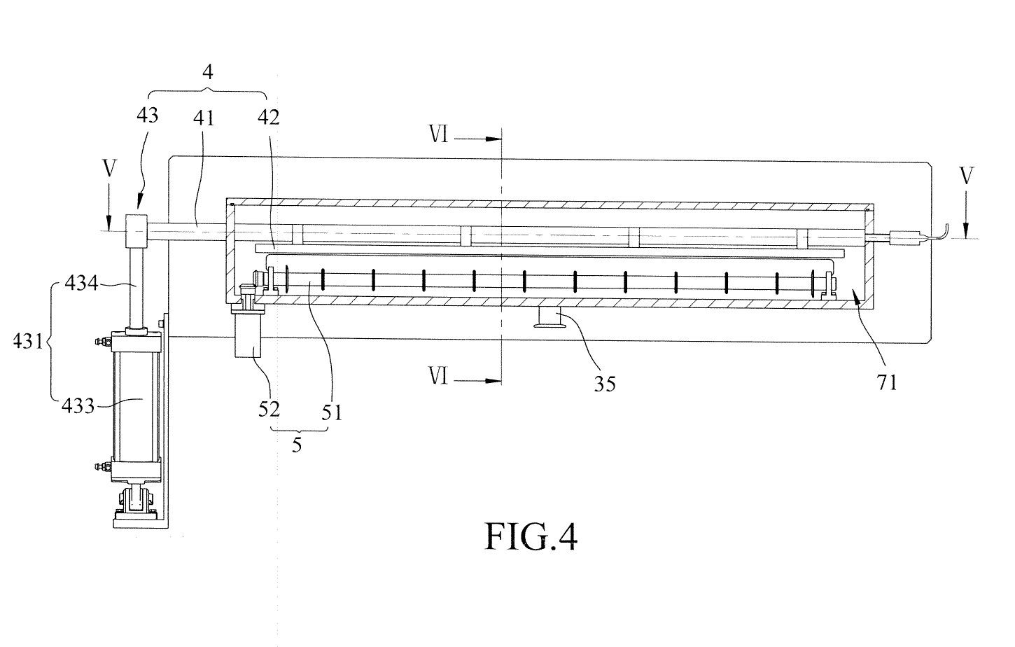

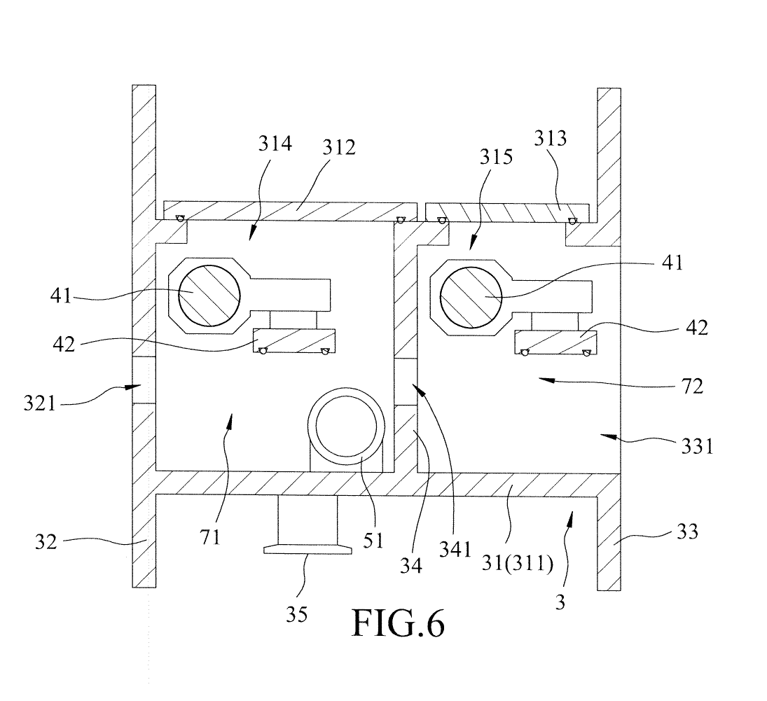

Referring to FIGS. 4 and 6, an exemplary embodiment of a double-valve device includes a base unit 3, two valve units 4 and a transport unit 5.

Referring to FIG. 6, the base unit 3 has a surrounding wall 31, an entrance wall 32 connected to one side of the surrounding wall 31 and formed with an entrance opening 321, an exit wall 33 connected to another side of the surrounding wall 31 oppositely of the entrance wall 32 and formed with an exit opening 331, and a spacing wall 34 disposed between the entrance and exit walls 32, 33 and formed with a pass-through opening 341. A maximum distance between the entrance and exit walls 32, 33 is not greater than 500 millimeters. The surrounding wall 31, the entrance wall 32 and the spacing wall 34 cooperatively define a buffer chamber 71. The surrounding wall 31, the spacing wall 34 and the exit wall 33 cooperatively define a joint chamber 72. The surrounding wall 31 includes a main body 311, a buffer chamber sealing plate 312 and a joint chamber sealing plate 313. The main body 311 is formed with a buffer chamber service entrance 314 that communicates the buffer chamber 71 and that is sealed by the chamber sealing plate 312, and a joint chamber service entrance 315 that communicates the joint chamber 72 and that is sealed by the joint chamber sealing plate 313. The base unit 3 further has a pumping hole 35 that is in spatial communication with the buffer chamber 71.

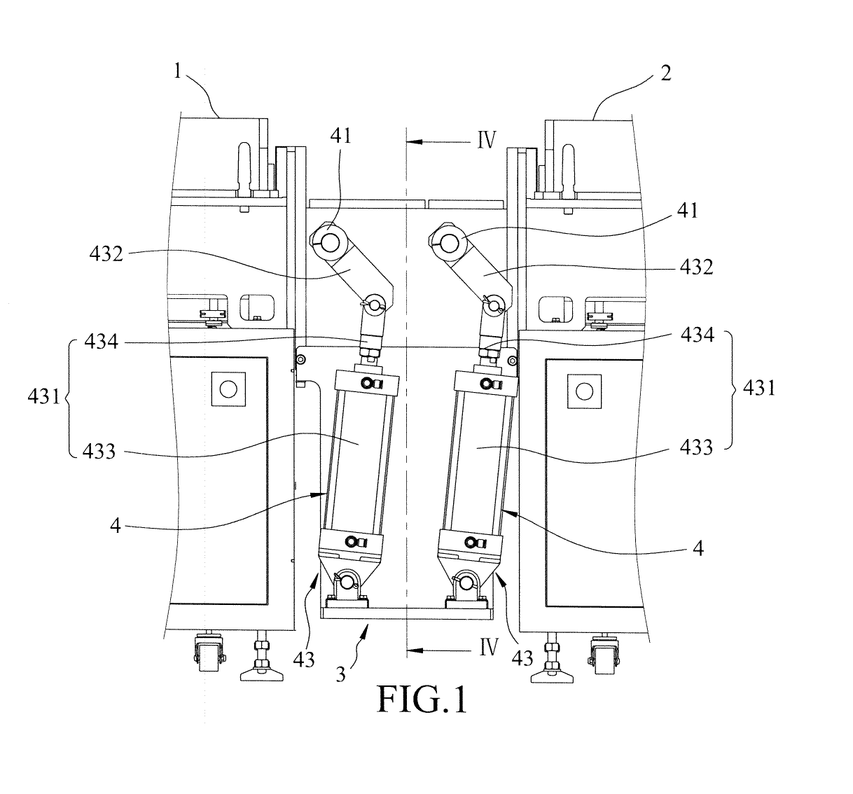

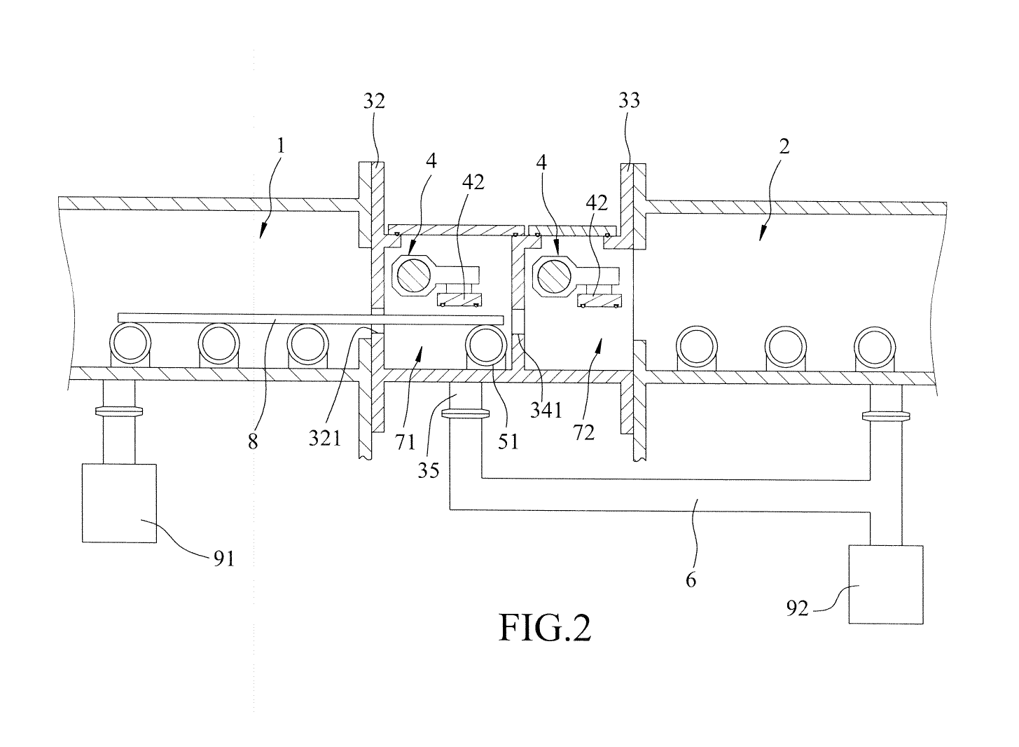

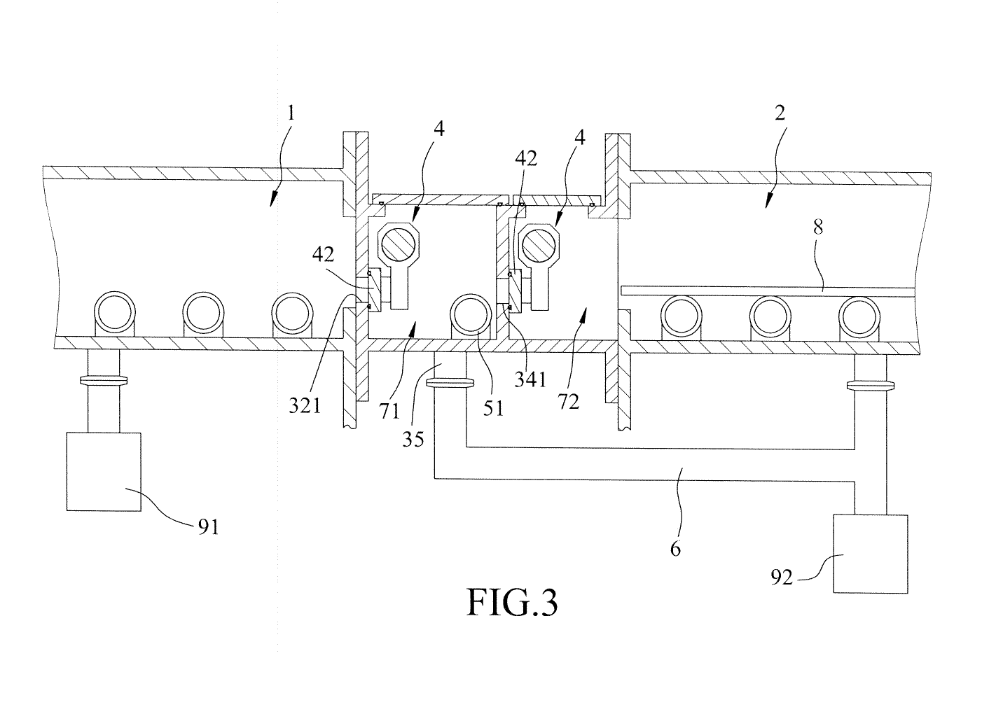

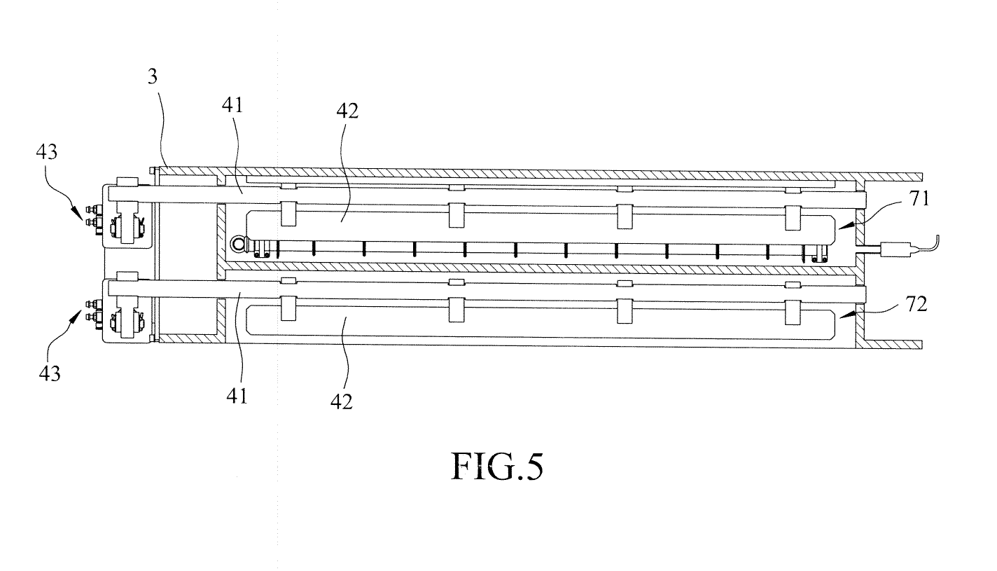

Referring to FIGS. 1, 2 and 5, the two valve units 4 are respectively disposed in the buffer and joint chambers 71, 72 for respectively sealing and unsealing the entrance and pass-through openings 321, 341. Each valve unit 4 includes a rotation shaft 41 rotatably mounted to the base unit 3, a valve door 42 co-rotatably connected to the rotation shaft 41, and a driver 43 connected between the base unit 3 and the rotation shaft 41. The driver 43 of each of the valve units 4 includes a cylinder 431 and a connecting rod 432. The cylinder 431 includes a cylinder body 433 connected pivotally to the base unit 3, and a piston 434. The connecting rod 432 is connected pivotally between the rotation shaft 41 and the piston 434. The driver 43 drives the rotation shaft 41 to rotate between a sealing position (see FIG. 3) and an unsealing position (see FIG. 2).

Referring to FIG. 4, the transport unit 5 includes a roller 51 that is rotatably disposed in the buffer chamber 71, and a motor 52 for driving rotation of the roller 51.

For one of the valve units 4 corresponding in position to the buffer chamber 71, when the piston 434 of the driver 43 is retracted into the cylinder body 433, the connecting rod 432 is driven by the piston 434 to drive rotation of the rotation shaft 41 to the sealing position, where the valve door 42 seals the entrance opening 321. When the piston 434 is extended out of the cylinder body 433, the connecting rod 432 is driven by the piston 434 to drive a reverse rotation of the rotation shaft 41 to the unsealing position, where the valve door 42 unseals the entrance opening 321. Likewise, for the other one of the valve units 4 corresponding in position to the joint chamber 72, when the rotation shaft 41 is at the sealing position, the valve door 42 seals the pass-through opening 341. When the rotation shaft 41 is at the unsealing position, the valve door 42 unseals the pass-through opening 341. Therefore, even if the valve door 42 in the buffer chamber 71 is unable to hermetically seal the entrance opening 321 due to deposition on the valve door 42 after long-term use or mechanical malfunction, the valve door 42 in the joint chamber 72 is still capable of hermetically sealing the pass-through opening 341, so that chamber isolation can be achieved.

It is worth mentioning that the exemplary embodiment of the double-valve device may be independently manufactured or sold, or may be mounted between a process chamber 1 and an unload chamber 2 of a film deposition apparatus in such a manner that, as shown in FIGS. 1 and 2, the entrance wall 32 of the base unit 3 is adapted to be hermetically connected to the process chamber 1, and the exit wall 33 is adapted to be hermetically connected to the unload chamber 2. The film deposition apparatus includes a first pump 91, a second pump 92 and a gas line 6. The first pump 91 is used for pumping down the process chamber 1. The second pump 92 is used for pumping down the unload chamber 2. One end of the gas line 6 is connected to the pumping hole 35 and another end of the gas line 6 is connected to the second pump 92. Since the maximum distance between the entrance and exit walls 32, 33 is not greater than 500 millimeters, the buffer chamber 71 has a small volume that does not require a dedicated pump to be pumped down to vacuum. Therefore, the second pump 92 can be used for the unload chamber 2 and the buffer chamber 71. The cost of manufacturing the film deposition apparatus is thus reduced.

As shown in FIG. 2, after a workpiece 8 is processed in the process chamber 1, the valve door 42 in the buffer chamber 71 is operated to unseal the entrance opening 321 of the entrance wall 32 and the valve door 42 in the joint chamber 72 is simultaneously operated to unseal the pass-through opening 341 of the spacing wall 34, so that the workpiece 8 is conveyed from the process chamber 1, through the buffer chamber 71 and the joint chamber 72, and toward the unload chamber 2 by the roller 51 of the transport unit 5.

Then, as shown in FIG. 3, after the workpiece 8 is completely transferred into the unload chamber 2, the valve door 42 in the buffer chamber 71 and the valve door 42 in the joint chamber 72 are operated to simultaneously and respectively seal the entrance opening 321 and the pass-through opening 341. Therefore, the process chamber 1 can be pumped down to ultrahigh vacuum for processing another workpiece, and, meanwhile, the unload chamber 2 may be vent to atmospheric pressure for removal of the workpiece 8 from the unload chamber 2. If the valve door 42 in the buffer chamber 71 is not capable of hermetically sealing the entrance opening 321 due to film deposition on the valve door 42 after long-term use, or the valve door 42 in the joint chamber 72 is not capable of hermetically sealing the pass-through opening 341 due to mechanical malfunction, the buffer chamber 71 can still be continuously pumped down by the second pump 92 to maintain a vacuum status and keep ambient contaminants from entering into the process chamber 1 and causing the film quality of deposition to be adversely affected. Besides, the buffer chamber 71 and the unload chamber 2 share the second pump 92, so that the pressure difference between the buffer chamber 71 and the joint chamber 72 is not significant. Therefore, the valve door 42 in the joint chamber 72 can be more effectively driven by the driver 43.

To sum up, by virtue of the double-valve configuration of the present disclosure, the process chamber 1 can be better sealed and protected from gas leakage and ambient contaminants.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A double-valve device adapted to be mounted between a process chamber and an unload chamber of a film deposition apparatus, said double-valve device comprising:
a base unit that has a surrounding wall, an entrance wall connected to one side of said surrounding wall and formed with an entrance opening, an exit wall connected to another side of said surrounding wall oppositely of said entrance wall and formed with an exit opening, and a spacing wall disposed between said entrance and exit walls and formed with a pass-through opening, a maximum distance between said entrance and exit walls being not greater than 500 millimeters, said surrounding wall, said entrance wall and said spacing wall cooperatively defining a buffer chamber, said surrounding wall, said spacing wall and said exit wall cooperatively defining a joint chamber, said entrance wall being adapted to be hermetically connected to the process chamber, said exit wall being adapted to be hermetically connected to the unload chamber, said base unit further having a pumping hole that is in spatial communication with said buffer chamber;
two valve units that are respectively disposed in said buffer and joint chambers for respectively sealing and unsealing said entrance and pass-through openings; and
a transport unit that includes a roller rotatably disposed in said buffer chamber.

2. The double-valve device as claimed in claim 1, wherein:
each valve units includes a rotation shaft rotatably mounted to said base unit, a valve door co-rotatably connected to said rotation shaft, and a driver connected between said base unit and said rotation shaft for driving said rotation shaft to rotate between a sealing position and an unsealing position;
when said rotation shaft of one of said valve units, which is disposed in said buffer chamber, is at the sealing position, said valve door of said one of said valve units seals said entrance opening, and when said rotation shaft of said one of said valve units is at the unsealing position, said valve door of said one of said valve units unseals said entrance opening; and
when said rotation shaft of the other one of said valve units, which is disposed in said joint chamber, is at the sealing position, said valve door of said other one of said valve units seals said pass-through opening, and when said rotation shaft of said other one of said valve units is at the unsealing position, said valve door of said other one of said valve units unseals said pass-through opening.

3. The double-valve device as claimed in claim 1, wherein said surrounding wall includes a main body, a buffer chamber sealing plate and a joint chamber sealing plate, said main body being formed with a buffer chamber service entrance that communicates said buffer chamber and that is sealed by said chamber sealing plate, and a joint chamber service entrance that communicates said joint chamber and that is sealed by said joint chamber sealing plate.

4. The double-valve device as claimed in claim 2, wherein said driver of each of said valve units includes:
a cylinder that includes
a cylinder body connected pivotally to said base unit, and
a piston; and
a connecting rod that is connected pivotally between said rotation shaft and said piston.

5. The double-valve device as claimed in claim 1, wherein said transport unit further includes a motor for driving rotation of said roller.
